(19) United States
(12) Patent Application Publication
(10) Pub. No.: US 2011/0277835 A1
(43) Pub. Date: Nov. 17, 2011

(54) SOLAR CELL WITH SPLIT GRIDLINE PATTERN

(75) Inventors: Denis Paul MASSON, Ottawa (CA); Simon FAFARD, Ottawa (CA)

(73) Assignee: CYRIUM TECHNOLOGIES INCORPORATED, Ottawa (CA)

(21) Appl. No.: 13/178,074

(22) Filed: Jul. 7, 2011

Related U.S. Application Data
(60) Provisional application No. 61/367,072, filed on Jul. 23, 2010.

(51) Int. Cl. H01L 31/0216

(52) U.S. Cl. 136/256

(57) ABSTRACT

A solar cell with an electrical gridline pattern that includes a lower density of gridlines in a central portion of a light-input surface of the solar cell, and a higher density of gridlines adjacent the busbars of the solar cells.

### CROSS REFERENCE TO RELATED APPLICATIONS

This application claims the benefit of priority of U.S. Provisional Patent Application No. 61/367,072 filed Jul. 23, 2010, which is incorporated herein by reference in its entirety.

### FIELD

The present disclosure relates generally to solar cells. More particularly, the present disclosure relates to electrical grid patterns on the light-input surface of solar cells.

### BACKGROUND

Electrical current generated in a solar cell is typically provided to a load through a front electrode and a back electrode formed on the solar cell. In the field of concentrated photovoltaics (CPV), the electrical current generated within the solar cell can be substantial. As such, for solar cells that have a square or rectangular light-input surface, in order to be able to efficiently accommodate such substantial electrical currents, the light-input surface will generally have formed thereon a series of equi-spaced parallel, linear electrical conductor that interconnect, physically and electrically, a pair of busbars formed on opposite sides of the light-input surface of the solar cell. The linear electrical conductor elements can be referred to as gridlines.

However, the gridlines produce a shadow on the solar cell, which means that the solar cell material that lies in the shadow of the gridlines does not receive light and, therefore, does not contribute photo-generated carriers (electrons and holes) that give rise to the electrical current generated in the solar cell. As the solar cell material can be very expensive, designers aim to minimize the shadow produced by the gridlines. That is, on the one hand, designers will want to have as narrow and/or as few gridlines as possible. But, on the other hand, decreasing the width and/or the number of gridlines, can result in decreased performance metrics (for example, conversion efficiency, series resistance, and fill factor) due to resistive power loss (Joule's first law). Namely, the electrical power dissipated (lost) in the form of heat: Pₗₒₛₜ=RₛI², where Rₛ is the effective series resistance of the linear conductor and I is the electrical current flowing therethrough. Therefore, designers face a tradeoff problem between the number and width of gridlines and the electrical power dissipation through the gridlines.

At a given illumination intensity, and for a given type of grid line cross-section and conductivity, there is an optimum gridline separation to maximize the conversion efficiency (and other performance metrics) of a solar cell. Beyond the optimum gridline separation, the performance of the solar cell will decrease because of increases in resistive losses in the gridlines because each individual gridline needs to support a higher current. A potential strategy to decrease the shadowing while keeping the same conductivity in the individual grid line is to make the grid lines thinner but higher so that their cross-section remains the same. Typical Cross-sections of gridlines for III-V semiconductor three-junction solar cells are 5-6 μm wide by ˜5-6 μm high, often with a trapezoid shape inherent to their manufacturing process. In principle, a gridline with a width of 1 μm and a height of 25 μm would have the same conductivity as a 5 μm×5 μm gridline, but would cast less shadow and therefore allow for better performance of the solar cell. In practice however such lines are difficult to fabricate and can pose serious assembly and reliability issues because they would be prone to sagging and bending and therefore more fragile under wet and spray cleaning and rinsing during manufacturing or during operation. Such gridlines would also be very fragile and subject to damage in the assembly lines.

Another issue with present gridline designs (gridline pattern) relates to local overheating combined with thermal expansion mismatches, which can lead to dielectric fractures, de-lamination, metal fatigue and corrosion leading to a degradation in performance and potential failures. Semiconductor materials used in solar cell applications are particularly prone to such thermal issues because their opto-electrical properties can vary significantly with temperature which can lead, under certain conditions, to disastrous runaway failures. For example local heating due to high current density in a gridline in a specific region of a solar cell will tend to reduce the semiconductor bandgap in that area, which, in turn, depending on the conditions of operation, can locally further increase the current density because of the reduced semiconductor bandgap, giving rise to the run away catastrophic failure.

Improvements in solar cell gridline design are therefore desirable.

### SUMMARY

It is an object of the present disclosure to obviate or mitigate at least one disadvantage of previous solar cell gridline patterns.

In a first aspect there is provided a solar cell that comprises: a light-input surface to receive light; a busbar formed at a periphery of the light-input surface; a plurality of elements formed atop the light-input surface. The elements are electrical conductor elements. The plurality of elements is arranged in a least two groups, a first group of the at least two groups having a first number of elements, a second group of the at least two groups having a second number of elements, the first number being smaller than the second number, the second group being formed on the light-input surface between the busbar and the first group, the elements of the second group being electrically connected to the bus bar, the elements of the first group arranged to provide an electrical current propagating therein to the elements of the second group.

The elements of the second group are substantially perpendicular to the busbar. Further, the solar cell can comprise a bridging electrical conductor element that electrically interconnects the elements of the second group. The elements of the first group can be electrically connected to the bridging electric conductor element. The bridging electrical conductor element can be substantially straight. The elements of the first group can be substantially parallel to each other. The elements of the first group can be substantially perpendicular to the busbar.

The solar cell of the first aspect can further comprise a plurality of bridging electrical conductor elements, each bridging electrical conductor element to electrically interconnect a pair of elements of the second group. Each element of the first group can be electrically connected to one bridging electrical conductor element. Each bridging electrical conductor element can be substantially straight. Each bridging electrical conductor element can be arcuate. Each bridging electrical conductor element can be V-shaped.

In the solar cell of the first aspect, each element of the second group can have a first end and a second end, the first end can be physically connected to the busbar and the second end can be physically connected to the second end of another element of the second group. A ratio of the second number to the first number can be two, and each element of the first group can have an end physically connected to a pair of second ends.

In the solar cell of the first aspect, some of the elements can be tapered elements with a tapered width. The tapered elements can have side walls that are straight along a length of the tapered elements.

In the solar cell of the first aspect, the tapered elements can have side walls that are curved along a length of the tapered elements.

In the solar cell of the first aspect, some of the elements can be tapered elements with a tapered height.

The solar cell of the first aspect can further comprise: a backside; and a plurality of gridlines formed on the backside, the plurality of gridlines formed on and electrically connected to the backside, the plurality of gridlines forming a gridline pattern on the backside.

Other aspects and features of the present disclosure will become apparent to those ordinarily skilled in the art upon review of the following description of specific embodiments in conjunction with the accompanying figures.

### BRIEF DESCRIPTION OF THE DRAWINGS

Embodiments of the present disclosure will now be described, by way of example only, with reference to the attached Figures.

FIG. 1 shows a front view of a prior art solar cell.

FIG. 2 shows a side view of the prior art solar cell of FIG. 1.

FIG. 3 shows a top view of the prior art solar cell of FIG. 1 with arrows indicating current flow and current intensity.

FIG. 4 shows a top view of an embodiment of a solar cell of the present disclosure.

FIG. 5 shows a top view of another embodiment of a solar cell of the present disclosure with arrows indicating current flow and current intensity.

FIG. 6 shows a top view of yet another embodiment of a solar cell of the present disclosure.

FIG. 7 shows a top view of an additional embodiment of a solar cell of the present disclosure with arrows indicating current flow and current intensity.

FIG. 8A shows a top view of another additional embodiment of a solar cell of the present disclosure.

FIG. 8B shows a top view of yet another embodiment of a solar cell of the present disclosure.

FIG. 9 shows a side view of gridline with a tapered height.

FIG. 10 shows a top view of a further embodiment of the present disclosure.

FIG. 11 shows a close-up, top view, of a gridline and busbars of an embodiment of a solar cell of the present disclosure.

FIG. 12 shows a series of gridlines connected to a busbar in an embodiment of a solar cell of the present disclosure.

FIG. 13 shows a top view of another embodiment of a solar cell of the present disclosure.

FIG. 14 shows a top view of another embodiment of a solar cell of the present disclosure.

FIG. 15 shows a top view of another embodiment of a solar cell of the present disclosure.

FIG. 16 shows a top view of another embodiment of a solar cell of the present disclosure.

FIG. 17 shows a top view of another embodiment of a solar cell of the present disclosure.

FIG. 18 shows a plot of conversion efficiency of a solar cell as a function of solar concentration. and

FIG. 19 shows a backside of a solar cell on which is formed a gridline pattern.

### DETAILED DESCRIPTION

Generally, the present disclosure provides solar cells with increased performance metrics (e.g., conversion efficiency) while keeping electrical resistive losses to a minimum. This is achieved by replacing the traditional parallel and equi-spaced gridlines by a gridline design where gridlines are split to reduce shadowing while keeping resistive losses to an acceptable level. The present disclosure also reduces the risk of failures from overheated gridlines by having the gridlines arranged in split grid pattern that causes the current density in the gridlines to decrease in comparison to prior art designs.

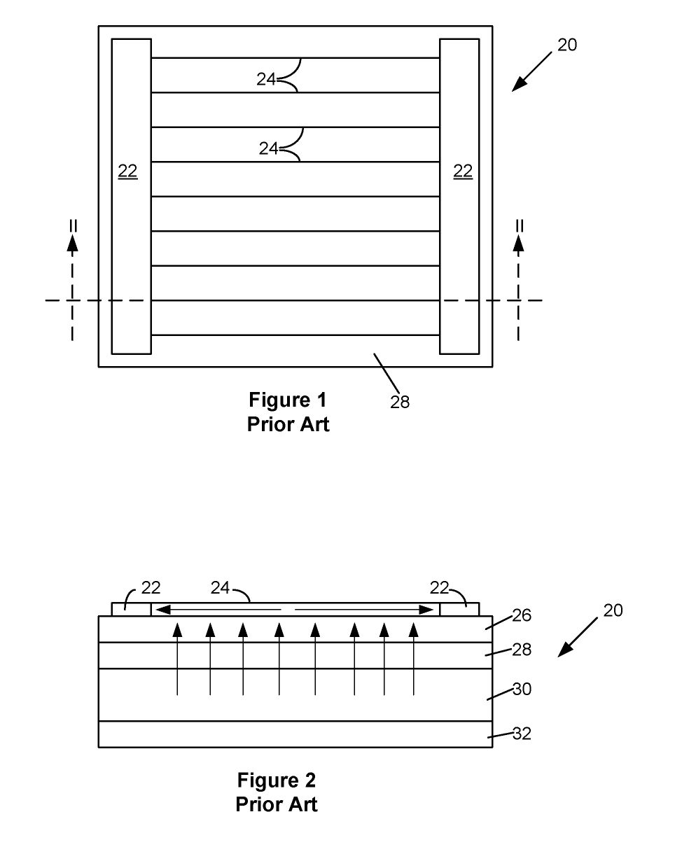

FIG. 1 shows a top view of a prior art solar cell 20 that has formed thereon a pair of busbars 22 interconnected, electrically and physically by gridlines 24. The busbars 22 and the gridlines 24 can be formed of the same metal, for example, gold. The busbars 22 and the gridlines 24 are typically formed on a cap layer 26 (shown at FIG. 2) of the solar cell 20, which is formed atop the window layer 28. The gridlines 24 are equi-spaced and carry the current produced by the underlying solar cell to the two busbars 22. What is important to understand in this prior art design is how the current flows and where resistive losses occur. Except for the areas shadowed by the grid lines, a uniform current is generated below the level of the gridlines 24 when a uniform illumination is applied. This current initially travels predominantly upwards (as shown by the arrows at FIG. 2), perpendicular to the solar cell light-input surface (plane) until it reaches the front surface. This is in part because the vertical dimensions are typically much smaller than the lateral dimensions.

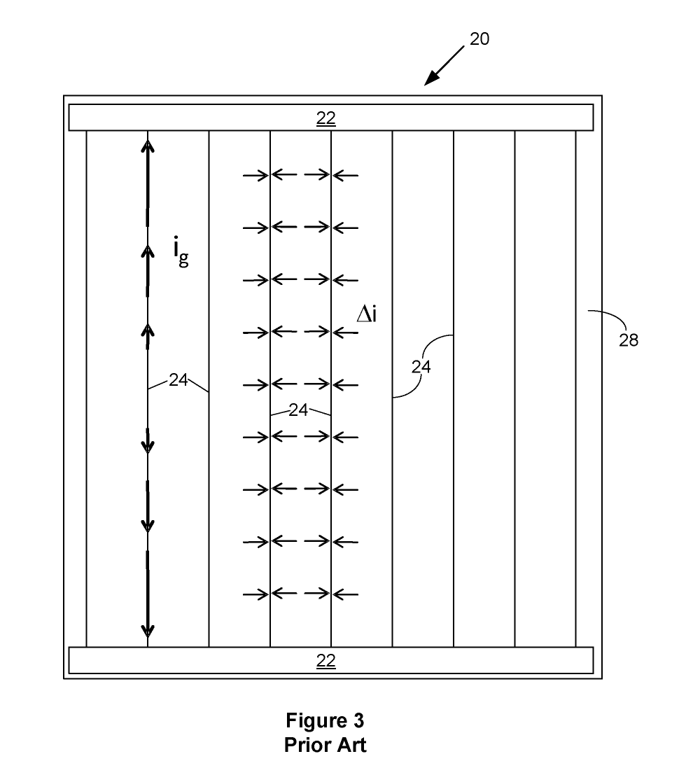

At that point, the current can travel laterally in a layer often called the window layer 28 and/or the emitter layer before reaching the closest gridline 24. The emitter and/or the window layers typically have a higher electrical conductivity compared to the base layer of the solar cell. Arrows in FIG. 3 show the electrical current flowing into gridlines 24 and from gridlines 24 to the busbars 22. A key point to note is that current becomes increasingly larger in any given gridline 24 from the centre of the solar cell 20 to the point where the gridline 24 connects to the busbar 22 because the solar cell is typically illuminated over its entire light-input surface. This is because the electrical current generated uniformly by the underlying cell accumulates along the gridlines 24 as it approaches the busbars 22. As will be understood by the skilled worker this implies more gridline resistive losses near the busbars than in the centre of the solar cell 20. This is because, as mentioned previously, the losses vary as ˜R_{g}I_{g}², where R_{g} is the grid line resistivity per unit length and I_{g} the local current at a given point along a gridline.

FIG. 2 shows a cross-sectional view of the solar cell 20 of FIG. 1 taken along the line II-II. As shown at FIG. 2, the cap layer 26 is formed on a window layer 28, which is formed atop a p-n junction 30 (or more than one more p-n junctions electrically connected in series). The p-n junction 30 (or the multiple p-n junctions) is formed atop a substrate 32 that can have formed, on its back surface, an electrical contact to connect to a load.

As photo-carriers are generated by light absorbed in the p-n junction 30, an electrical current flows from the p-n junction 30 upward (arrows pointing upwards) to the gridlines 24 and from there, laterally (arrows pointing sideways) to the busbars 22. As mentioned above, the current initially travels predominantly upwards because the vertical dimensions are typically much smaller than the lateral dimensions. FIG. 3 shows a top view of the solar cell 20. At FIG. 3, the small lateral arrows that terminate on gridlines 24 indicate electrical current Δi flowing into the gridlines 24. The vertical arrows shown on of the gridlines 24 indicate an electrical current i_{g} that increases as a function of decreasing distance from the nearest busbar 22. As such, for gridlines having a constant cross-section, the density of current increases along any given gridline 24 as the distance towards the closest busbar 22 diminishes.

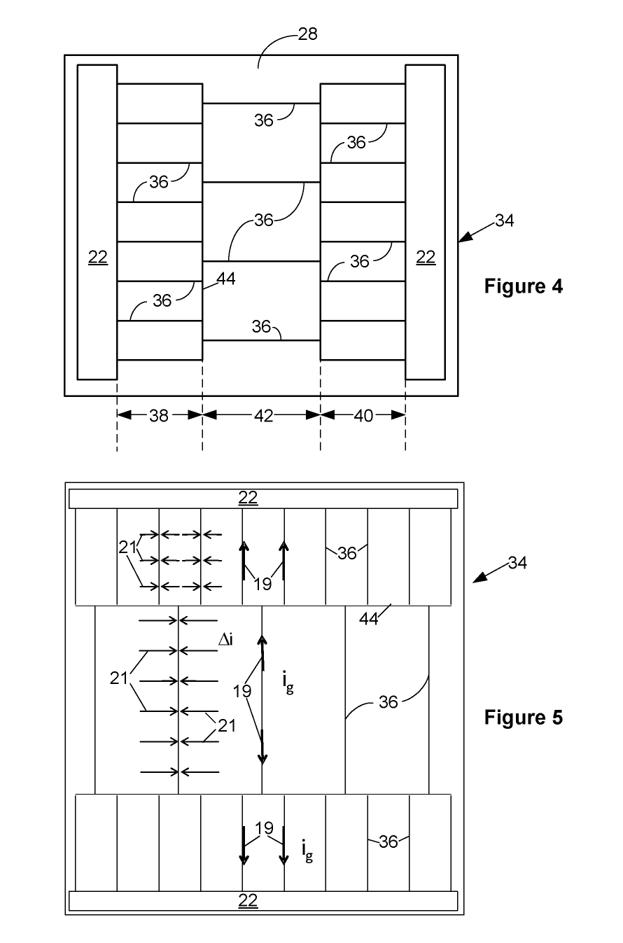

FIG. 4 shows a first embodiment of a solar cell 34 of the present disclosure. The solar cell 34, which has at least one p-n junction formed therein, has a pair of busbars 22 that are parallel to each other (although they need not be), and a plurality of electrical conductor elements 36 that are formed on the cap layer (not shown) of the solar cell 34. The busbars 22 are shown formed on the solar cell 34, at the periphery thereof. However, in some embodiments, the busbars 22 can be formed at the periphery of the solar cell, but on a carrier adjacent the solar cell. The cap layer is formed on the window layer 28 of the solar cell 34. The electrical conductor elements 36 can also be referred to as gridlines. In the present embodiment, the electrical conductor elements 36 are arranged in three groups: a first group 38, a second group 40, and a third group 42. The first group 38 has a first number (e.g., 8) of electrical conductor elements 36 that are perpendicular (although they need not be) to the leftmost busbar 22 and that are physically connected to the leftmost busbar 22. The second group 40 has a second number (e.g., 8) of electrical conductor elements 36 that are perpendicular (although they need not be) to the rightmost busbar 22 and that are physically connected to the rightmost busbar 22. The third group 42 has a third number (e.g., 4) of electrical conductor elements 36 that are perpendicular (although they need not be) to the leftmost and rightmost busbars 22. The electrical conductor elements 36 of the third group are electrically connected to the electrical conductors elements 36 of the first group 38 and the second group 40 through conductor elements 44 (which can also be referred to as a bridging electrical conductor element or as a transverse electrical conductor element).

As electrical current flows from any electrical conductor element 36 of the third group 42 to electrical conductor elements 36 of the first group 38 (or second group 40), the current density in any given electrical conductor elements 36 of the first group 38 (or second group 40) will be half the current density that is present in an electrical conductor element 36 of the third group 42 at the junction of the electrical conductor element 36 of the third group 42 with electrical conductor elements 36 of the first group 38 or the second group 40. For clarity, the current is conserved and the current from electrical conductor elements 36 in the third group is split in half into the electrical conductor 44 connecting the third group 42 to the first group 38, and similarly on the other side connecting the third group to the second group 40.

FIG. 5 shows another embodiment of the solar cell 34. The arrows 21 show the solar cell current Δi flowing into gridlines 36. The arrows 19 show how the current I_{g} in the gridlines 36 is split as it reaches the gridlines that are physically connected to the busbars 22. In the solar cell 34, the maximum current density in any given gridline 36 is reduced compared to that in gridlines of the prior art embodiment of FIG. 1, assuming the latter has the same number of gridlines as that in the third group 42 of solar cell 34 and that the gridlines in the solar cell 20 and the solar cell 34 have the same shape, material and cross-section. The arrangement of the electrical conductor elements 36 in the embodiment of FIGS. 4 and 5, and in other embodiments described below, can be referred to as a split gridline design.

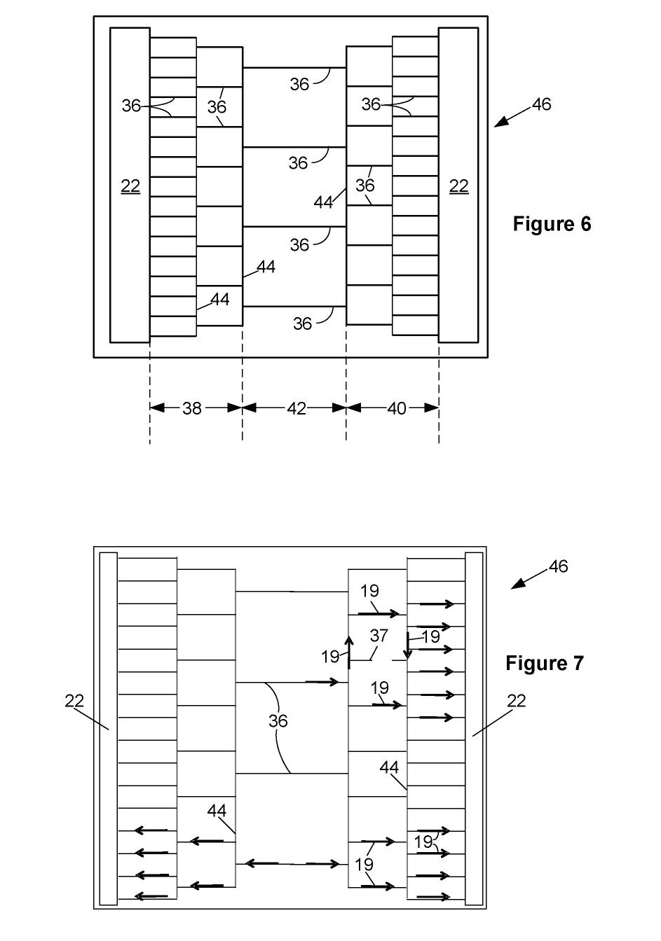

FIG. 6 shows another embodiment of a solar cell 46 of present disclosure. In the solar cell 46, the gridlines 36 in the first group 38 and the second group 40 are further split as they approach there respective closest busbar 22.

FIG. 7 shows another embodiment of the solar cell 46, which has a broken gridline 37. In the prior art solar cell 20 of FIG. 1, any break in a gridline would considerably hinder the performance of the solar cell 20. Advantageously, the split gridline design of the present disclosure allows for a simple redistribution of current (see arrows 19 near broken gridline 37) from the broken gridline 37 to neighbor gridlines. In the event of to a break in a gridline or, in other words, an open-circuit section (here called an open) in a gridline, the local current will be re-routed. In the traditional gridline design of FIG. 1, an open will force the current to travel back to the busbars in the remaining branches. If the open is near one of the busbars, there will be one short and one long branch. No reliability issues is expected to occur from the short branch but a large current, potentially up to twice as much as in the other grid lines can accumulate in the longer branch, which could cause problems due to local heating as discussed above, particularly near the junction between the busbar and the gridline where current density is expected to be maximum. In addition, excessive current in a gridline, or portion thereof, could result in metal electro-migration and lead to eventual failures. Metal electro-migration is a well-known problem which occurs due to momentum transfer between conducting electrons and diffusing metal atoms. This is why, in applications where large currents are expected, such as in solar cells and especially CPV cells, fabrication foundries will typically set design rules for maximum current densities in the conducting lines. Fabrication costs, fabrication capability and device performance may prevent a typical foundry from simply increasing the metal thickness and width to cope with larger currents. In fact foundries are expected to use the minimum metal thickness allowed to lower fabrication cost, thus lowering their current density design rule limit. In large volume production, it is expected that some devices with gridline breaks will pass inspection, the so-called escapes, leading to the problems described above. In the present disclosure, the splits in the gridline designs (FIG. 7) allow the current to by-pass the open and to find the combination of paths leading to the minimum resistance.

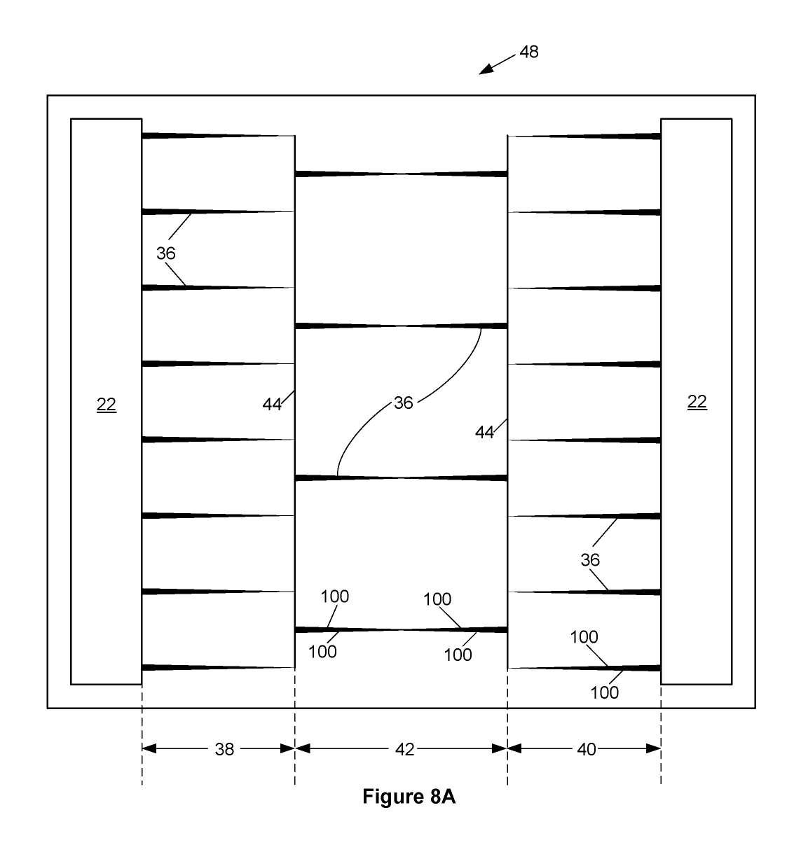

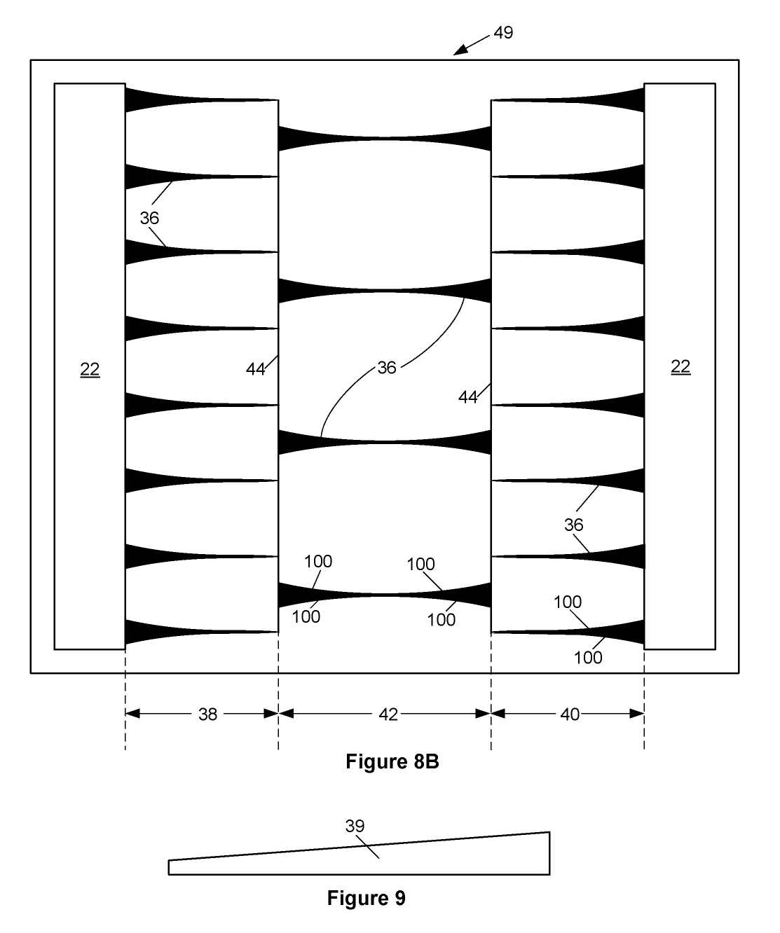

A variation in the present disclosure allows increasing a solar cell's current density capacity while keeping a low series resistance of the gridlines by using tapered (flared) gridlines. Thinner gridlines near the centre of the solar cell provide more unobstructed area to allow more sunlight to reach the p-n junctions of the solar cell to provide an increase in current while wider gridlines closer to the busbars reduce gridlines resistive losses where current, and therefore resistive losses, are maximum. Fundamentally, this allows to better manage the current density in the metal gridlines. Practical considerations in the fabrication of the gridlines will normally limit the minimum grid line width attainable. FIG. 8A shows an embodiment of a solar cell 48 of the present disclosure. The gridlines 36 are tapered in that their width increases as the distance to the nearest busbar 22 decreases. In this embodiment, the sides 100 of the gridlines are substantially straight. Assuming constant height of the gridlines 36, the cross-section of the gridlines 36 also increases as the distance to the nearest busbar 22 decreases. As such, the increase in width and cross-section of the gridlines 36 means that they can take on more current without necessarily increasing the current density in the gridlines 36. FIG. 8B shows yet another embodiment of a solar cell 49 of the present disclosure. In the embodiment shown at FIG. 8B, the sides 100 of the gridlines are curved rather than straight. Any suitable curvature can be used such as, for example, a curvature in the form of a quadratic function or similar functions that can help sustain the increasing current in the gridline while approaching the busbar. The shape of the flare in the tapered width can also take into account any non-uniformities of the illumination profile, and can be evaluated by modeling or by experimentation. Gridlines with tapered width, such as shown in the embodiments of FIGS. 8A and 8B, can be used in others solar cells embodiments described in the present disclosure, including the prior art gridline pattern of FIG. 1. Further, gridlines with a tapered height are also within the scope of the present disclosure. FIG. 9 shows such a gridline 39, the height of which increases as the distance to the nearest busbar decreases. The top side of the gridline 39 is substantially straight; however, a curved, top side, having any suitable shape, is also within the scope of the present disclosure.

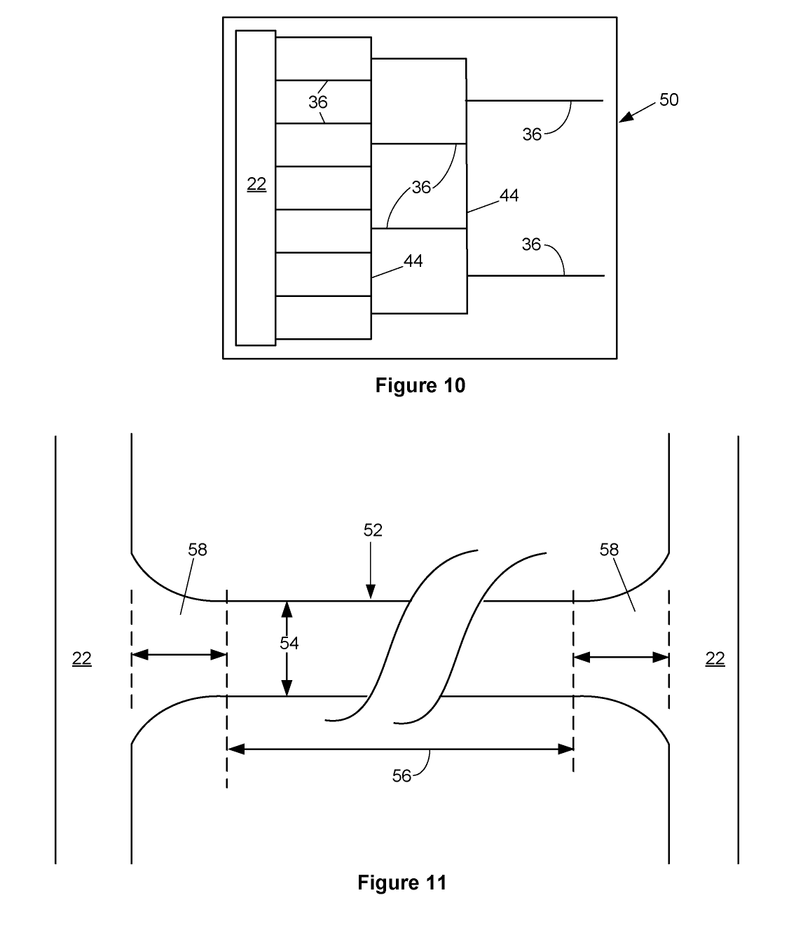

FIG. 10 shows another embodiment of a solar cell 50 of the present disclosure. The solar cell 50 has a split grid design but only one busbar 22. As in other embodiments, the sides of the gridlines 36 can be straight or curved. Similarly, the busbars themselves can have straight or curved sides (edges) without departing from the scope of the present disclosure.

FIG. 11 shows another embodiment of the present disclosure where the gridlines 52 can have a substantially constant width 54 and cross section along a middle portion 56, and a larger width and cross-section at end portions 58 and 60. Advantageously, in some CPV systems, the solar light concentrators are such that the light intensity decreases near the busbars 22. As such, having gridlines 52 that have an increased width adjacent the busbars 22, and thereby casting an increased shadow area on the active material below, is not, in such cases, a major concern since the amount of electricity generated in those areas is already low because of decreased illumination.

The following describes how an optimal position along a gridline, to split a gridline, may be calculated. The optimal position calculated below aims to maximize the power gain in a square solar cell with two busbars. The calculation balances the power gain from the increased current due to less shadowing from the gridlines, against the power loss due to the resistive effects in the gridlines and emitter (of the p-n junction connected to the window layer 28). Similar calculations can be done for non-square geometries.

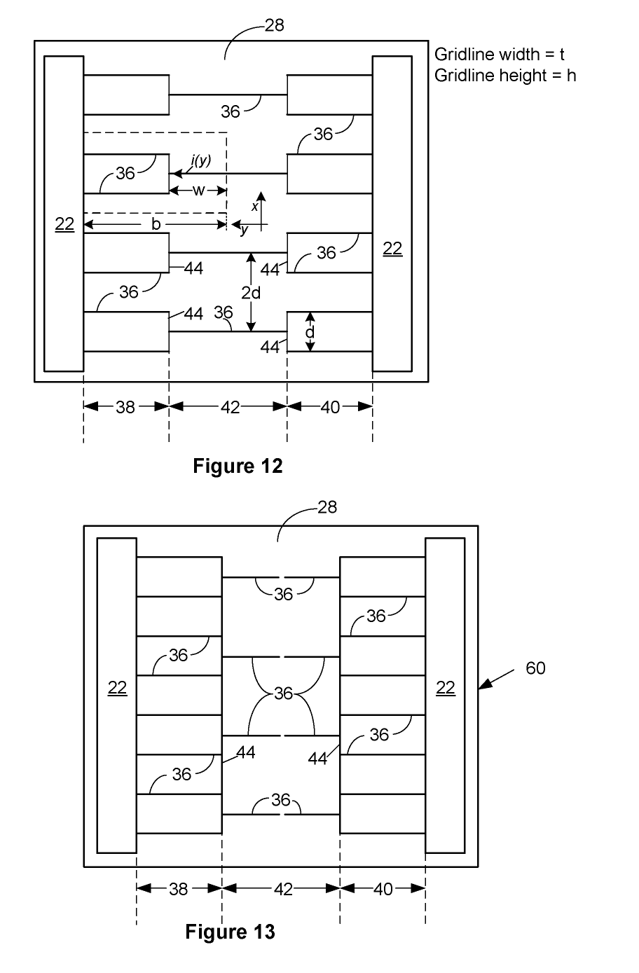

An embodiment of a split gridline pattern is shown at FIG. 12 for the case where bridging elements 44 electrically connect pairs of gridlines 36 in the first group 38 and in the second group 40. In the embodiment of FIG. 12, the gridline separation (spacing) in the first group 38 and in the second group 40 is d, while the gridline spacing in the third group 42 is 2d over a length 2w in the central area (third group) of the cell. Any suitable spacing between gridlines in the first, second, and third groups is also within the scope of the present disclosure. For example, the spacing between gridlines 36 in the first grouping 38 and/or the second grouping 40 could be significantly less than the spacing between gridlines 36 in the third grouping 42. This would occur with shorter length bridging elements 44, which would produce less shadowing. It is sufficient to perform the calculation on the area enclosed by the dotted lines since this unit is repeated across the solar cell. FIG. 12 has an (x,y) coordinate system. Assuming a constant voltage in the cell, the Gain in Power obtained by splitting the grid lines at y=w can be written as:

ΔP=VₘΔJₘ−ΔP_{rg}−ΔPᵣₑ (1)

where Vₘ is the Voltage in operation and ΔJₘ is the change in current when there is a split in the grid lines (w>0), ΔP_{rg} and ΔPᵣₑ are the added resistive power loss in the grid and Emitter when w>0. The change in current, ΔJₘ, is proportional to the change in shadowing from the gridlines. In the shaded area of FIG. 12, since t is typically much smaller than the width of the cell, the increase in current can be approximated by:

ΔJₘ=Jₘt(w−d) (2)

The resistive power loss due to the wire (gridline) bonds in that same area will depend on the resistance of the gridlines and the current they carry. Note that the current carried by a wire (gridline) varies with the distance from the centre of the cell:

i(y)=jₘsy (3)

where jₘ is the current density and s=2d−t, d being the spacing between gridlines, and t being the width of the gridline. The power loss in a small element of grid line can be written as:

dΔR_{rg}=i²(y)dr (4)

where dr=(ρ/th)dy with ρ being the resistivity of the grid line metal, h being the height of the gridline. The integrated resistive loss is then

$${\int }_{0}^{w} d Δ {P}_{rg} = \frac{1}{3} \frac{ρ {J}_{m}^{2} {s}^{2}}{th} {w}^{2} \qquad ( 5 )$$

There is also an additional resistive loss due to the small grid branches at the split:

$$Δ {P}_{d} = \frac{1}{4} \frac{ρ {J}_{m}^{2} {S}^{2}}{th} {w}^{2} \qquad ( 6 )$$

Similarly, one can show that the additional power loss in the emitter is

$$Δ {P}_{re} = \frac{1}{2} {J}_{m}^{2} w {σ}_{e} {d}^{3} \qquad ( 7 )$$

Where σₑ is the emitter sheet resistivity. From the above equations, one obtains:

$$Δ P = {V}_{m} {J}_{m} t ( w - d ) - \frac{ρ {J}_{m}^{2} {s}^{2} {w}^{2}}{th} ( \frac{w}{3} - \frac{d}{4} ) - \frac{1}{2} {J}_{m}^{2} w {σ}_{e} {d}^{3} \qquad ( 8 )$$

and the condition for maximum Power Gain, dΔP/dw=0 gives:

$${w}_{opt} = \frac{d}{4} \pm \sqrt{\frac{{d}^{2}}{16} + ( \frac{{V}_{m} {t}^{2} h}{ρ {J}_{m} {s}^{2}} - \frac{{σ}_{e} {thd}^{3}}{2 ρ {s}^{2}} )} \qquad ( 9 )$$

Assuming a gridline with silver metallization with dimensions given by h=t=6 μm, a pitch (spacing) of ˜d=100 μm and typical values expected for operation at 500 suns namely, Vₘ=2.8V, Jₘ=7 A/cm², σₑ=150Ω, one would find wₒₚₜ=3.5 mm. For a 10 mm×10 mm cell, this means 70% of the area in the centre of the cell would be re-designed to accommodate for grid lines with twice the pitch near the busbars. A corresponding relative gain of ˜0.8% or ˜0.3% absolute is then expected.

FIG. 13 shows another embodiment of a solar cell 60 of the present disclosure. As in the solar cell 34 of FIG. 4, the gridlines 36 are grouped into a first group 38, a second group 40, and a third group 42. The gridlines 36 in the third group 42 are spit in two parts.

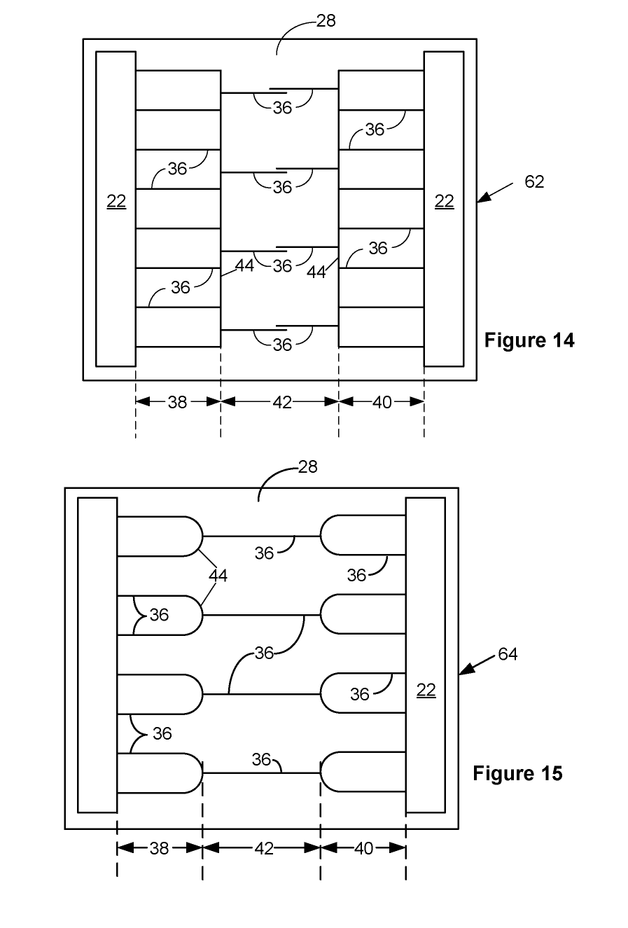

FIG. 14 shows another embodiment of a solar cell 62 of the present disclosure. As in the solar cell 60 of FIG. 14, the gridlines 36 in the third group 42 are split in two parts, which, as shown in the representation of FIG. 14, are spaced apart vertically and can overlap each other (although they do not need to overlap each other).

FIG. 15 shows another embodiment of a solar cell 64 of the present disclosure. In the solar cell 64, the gridlines 36 in the first group 38 and the second group 40 each have a straight portion electrically connected to a bridging electrical conductor element 44 that is arcuate (or curved). The bridging electrical conductor element 44 electrically connects the gridline 36 of the first group 38 to a gridline 36 of the third group 42.

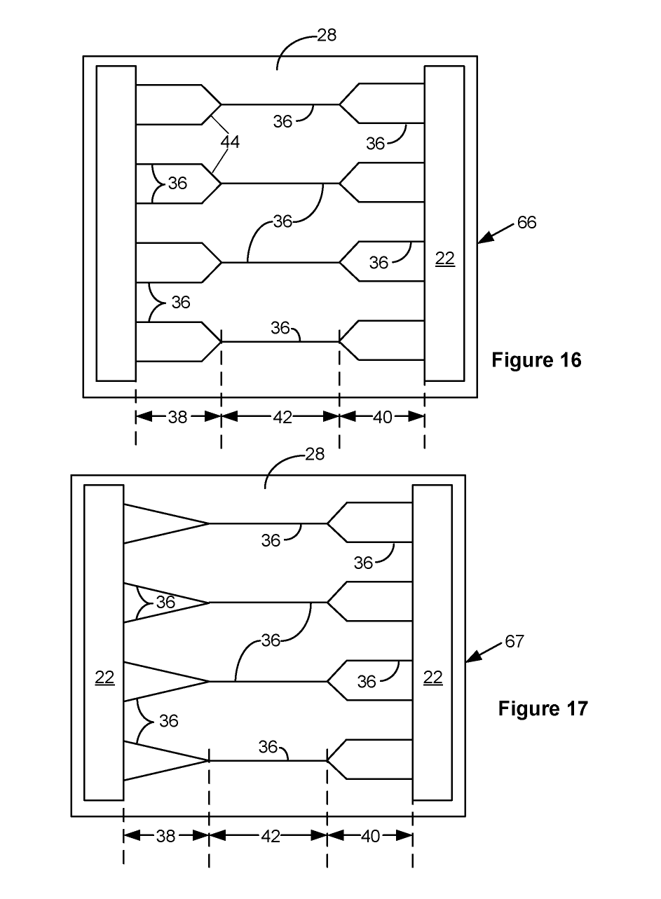

FIG. 16 shows another embodiment of a solar cell 66 of the present disclosure. In the solar cell 66, pairs of gridlines 36 in the first group 38 are electrically connected to a gridline 36 of the second group 40 through a V-shaped bridging electrical conductor element 44. In a variation of this embodiment or any of the previous embodiments, the distance between the branches formed by the pairs of gridlines 36 closer to the busbars, need not to be equally spaced. For example, in FIG. 16 the gridlines connected by the V-shaped bridging electrical conductor element 44 could be closer to each other compared to the spacing from the other V-shaped branch. This variation in the design can reduce the shadowing from the bridging electrical conductor elements 44, and therefore contribute to increasing the solar cell efficiency while keeping the series resistance the same.

FIG. 17 shows another embodiment of a solar cell 67 of the present disclosure. In the solar cell 67, pairs of gridlines 36 in the first group 38 are physically connected, at one end, to a busbar 22, and, at the opposite end, to another gridline.

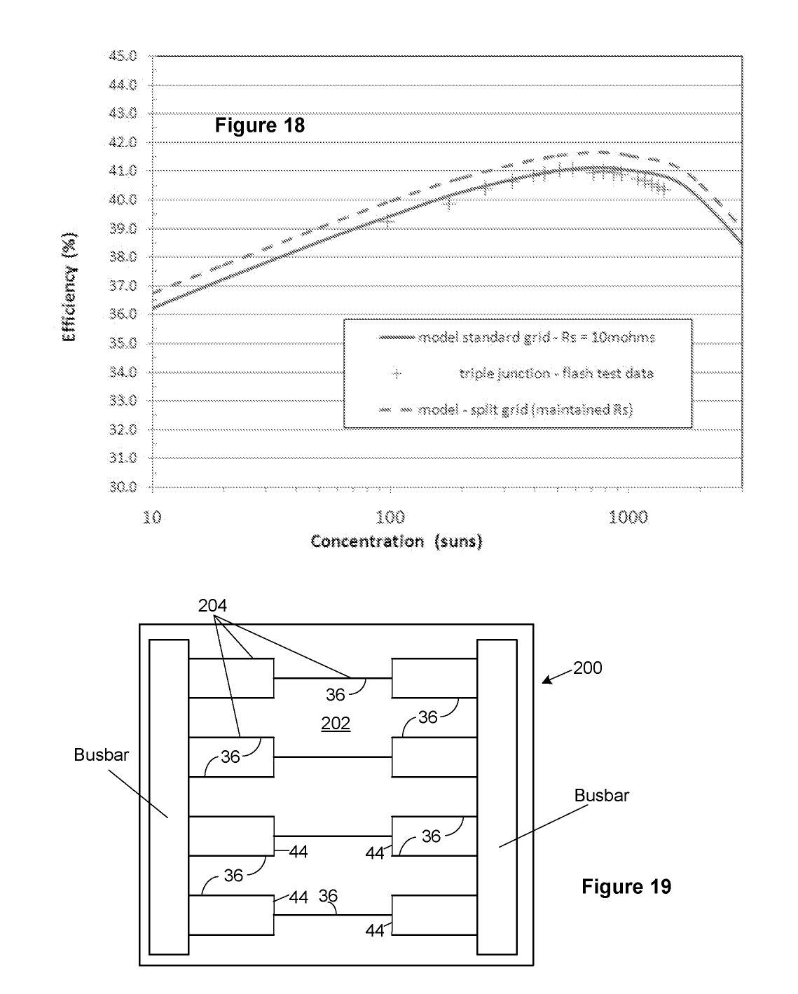

FIG. 18 shows a plot of conversion efficiency as a function of solar concentration for a three-junction solar cell that comprises self-assembled quantum dots and includes a gridline pattern similar to that shown in the solar cell 20 of FIG. 1. The crosses in FIG. 18 correspond to measured data. The solid line corresponds to modeled data for such a solar cell for a series resistance value (Rₛ) of 10 mohm. Based on the same model, and the same series resistance, an improvement of about 0.5% in conversion efficiency is expected with a gridline pattern as shown for the solar cell 46 of FIG. 6. Such an expected improvement is shown by the dash line in FIG. 18. The improvement in conversion efficiency is attributable to a reduction the shadowing caused by the gridline pattern shown at FIG. 6.

As will be understood by the skilled worker, the present disclosure also applies to rectangular or square cells having 4 busbars (one along each one of its 4 sides) instead of 2 busbars.

The above-noted embodiments relate to a gridline pattern formed on a light-input surface of a solar cell. However, the embodiments of gridline patterns may also be applied to the backside of solar cells without departing from the scope of the present disclosure. Such backside gridline metallization patterns can be used to replace blanket contacts, full or partial sheet metallization, or other opaque or semi-transparent contacts typically formed on solar cell backsides.

Advantageously, the application of the present gridline patterns to the backside of a solar cell could help concentrated infrared sunlight to escape the solar cell (transmit out of the solar cell) due to a decrease in reflection from the backside contact (a backside contact in the form of a gridline pattern will reflect less light than a blanket backside contact). This can result in a better thermal management of solar cells and therefore allow solar cells to run at cooler temperatures and higher performance. FIG. 19 shows a solar cell 200 with a backside 202, on which is formed a gridline pattern 204. The exemplary gridline pattern 204 comprises gridlines 36 and bridging elements 44. For exemplary purposes, the busbar geometry shown here in FIG. 19 is similar to the ones described for the light-input surface gridline pattern embodiments previously described, but given that the shadowing minimization requirements are not necessarily as critical for the backside metallization, the busbars could then be different. For example the backside busbars could be wider and occupy a larger fraction of the area than the busbars on the light-input surface of the solar cell, and/or be positioned on all four sides of the area. Such backside busbar geometries can still have the benefit of letting some infrared light escape the solar cell.

The gridlines shown and described in the exemplary embodiments above are generally elongated gridlines that can have a constant width and height, or that can be tapered. In some embodiments, the gridlines can have end portions that are tapered (flared) and an intermediate portion that has a constant cross-section shape throughout the length of the gridline. Gridline patterns comprising any suitable number of gridlines, to extract electrical current from any suitable optoelectronic device, are within the scope of the present disclosure. Any suitable material can be used in the manufacturing of the gridlines and any suitable manufacturing process can be used.

For example, electroplating can be used to form thick metal layers and gridlines. Clear areas where no gridlines are wanted can be obtained by masking these areas with known photolithography processes to prevent electro-deposition from occurring in these areas. Similarly, thick photoresist layers, bi-layers, or multi-layers can be used to define areas where no gridlines are wanted, followed by thick blanket metal depositions and subsequent lift-off processes to remove the metal in areas where lift-off photoresist has been patterned by photolithography. The thick metal layers can be preceded with ohmic metal deposition. The thick metal layers can be followed and/or protected with other, possibly thinner, metal depositions with different metals or materials that might be more stable to the ambient or to balance residual strains in the metal layers. For example a thin layer, often called a flash layer, of metal which has a low reaction rate with oxygen and/or humidity can follow the thick gridline formation. For example thick silver or copper gridlines can be used given their high conductivity, particularly for silver. Other metals which can be used for example for the thick high conductivity gridlines include aluminum, gold, nickel, zinc, or combination of those or other metals. A thin flash of gold can be used to protect the thick gridlines from oxidation, from humidity, or to change the reflectivity of the gridlines. The metal layers can be deposited by electron and/or ion beam sputtering, thermal evaporation, electroplating, or combination of these techniques or any other suitable techniques which can produce metal films in the sub-micrometer to several micrometer thicknesses.

As will be understood by the skilled worker, the gridline patterns of the present disclosure can be optimized for uniform illumination profiles or for non-uniform illumination profiles, depending on the application. The gridline patterns of the present disclosure can be applied not only to solar cells but also for other optoelectronic devices that can benefit from having a clear aperture with as little metallization (gridline) shadowing as possible while maintaining a low series-resistance. Such optoelectronic devices can include, for example, light emitting diodes requiring high optical efficiencies and high current densities.

In the preceding description, for purposes of explanation, numerous details are set forth in order to provide a thorough understanding of the embodiments. However, it will be apparent to one skilled in the art that these specific details are not required. In other instances, well-known electrical structures and circuits are shown in block diagram form in order not to obscure the understanding. For example, specific details are not provided as to whether the embodiments described herein are implemented as a software routine, hardware circuit, firmware, or a combination thereof.

The above-described embodiments are intended to be examples only. Alterations, modifications and variations can be effected to the particular embodiments by those of skill in the art without departing from the scope, which is defined solely by the claims appended hereto.

What is claimed is:

1. A solar cell comprising:
a light-input surface to receive light;
a busbar formed at a periphery of the light-input surface;
a plurality of elements formed atop the light-input surface, the elements being electrical conductor elements, the plurality of elements being arranged in a least two groups, a first group of the at least two groups having a first number of elements, a second group of the at least two groups having a second number of elements, the first number being smaller than the second number, the second group being formed on the light-input surface between the busbar and the first group, the elements of the second group being electrically connected to the bus bar, the elements of the first group arranged to provide an electrical current propagating therein to the elements of the second group.

2. The solar cell of claim 1 wherein the elements of the second group are substantially perpendicular to the busbar.

3. The solar cell of claim 2 further comprising a bridging electrical conductor element that electrically interconnects the elements of the second group.

4. The solar cell of claim 3 wherein the elements of the first group are electrically connected to the bridging electric conductor element.

5. The solar cell of claim 4 wherein the bridging electrical conductor element is substantially straight.

6. The solar cell of claim 4 wherein the elements of the first group are substantially parallel to each other.

7. The solar cell of claim 3 wherein the elements of the first group are substantially perpendicular to the busbar.

8. The solar cell of claim 1 further comprising a plurality of bridging electrical conductor elements, each bridging electrical conductor element to electrically interconnect a pair of elements of the second group.

9. The solar cell of claim 8 wherein each element of the first group is electrically connected to one bridging electrical conductor element.

10. The solar cell of claim 8 wherein each bridging electrical conductor element is substantially straight.

11. The solar cell of claim 8 wherein each bridging electrical conductor element is arcuate.

12. The solar cell of claim 8 wherein each bridging electrical conductor element is V-shaped.

13. The solar cell of claim 1 wherein each element of the second group has a first end and a second end, the first end being physically connected to the busbar and the second end being physically connected to the second end of another element of the second group.

14. The solar cell of claim 13 wherein:
a ratio of the second number to the first number is two; and
each element of the first group has an end physically connected to a pair of second ends.

15. The solar cell of claim 1 wherein some of the elements are tapered elements with a tapered width.

16. The solar cell of claim 15 wherein the tapered elements have side walls that are straight along a length of the tapered elements.

17. The solar cell of claim 15 wherein the tapered elements have side walls that are curved along a length of the tapered elements.

18. The solar cell of claim 1 wherein some of the elements are tapered elements with a tapered height.

19. The solar cell of claim 1 further comprising:
a backside; and
a plurality of gridlines formed on the backside, the plurality of gridlines formed on and electrically connected to the backside, the plurality of gridlines forming a gridline pattern on the backside.
